(19) United States
(12) Patent Application Publication
(10) Pub. No.: US 2012/0257365 A1
(43) Pub. Date: Oct. 11, 2012

(54) DEVICE FOR SECURING AT LEAST ONE CIRCUIT BOARD TO A RECEIVING ELEMENT

(75) Inventor: Jörg Söfker, Lemgo (DE)

(73) Assignee: PHOENIX CONTACT GmbH & Co. KG, Blomberg (DE)

(21) Appl. No.: 13/515,480

(22) PCT Filed: Dec. 17, 2010
(86) PCT No.: PCT/EP2010/007725

§ 371 Date: Jun. 12, 2012

(30) Foreign Application Priority Data
Dec. 17, 2009 (DE) 10 2009 059 013.7

(51) Int. Cl. H05K 7/00

(52) U.S. Cl. 361/784

(57) ABSTRACT

The invention relates to a device for securing at least one circuit board (14, 16, 18) to a receiving element (12) which receives the at least one circuit board (14, 16, 18) and comprises a securing element (20). Said securing element (20) at least partially traverses a through-opening (32) provided in the at least one circuit board (14, 16, 18). Said securing element (20) comprises a first maintaining element (36) which can be secured to the surface of the at least one circuit board (14, 16, 18) by means of a rotational movement of the securing element (20).

The invention relates to a device for securing at least one circuit board to a receiving element for receiving the at least one circuit board, wherein the securing is effected by means of at least one securing element.

A receiving element of this type is embodied in the form of a trough-shaped carrier element, for example, within which one or a plurality of circuit boards can be inserted in mounting elements provided on the receiving element. In order to fix the circuit boards in the receiving element, the mounting elements are usually shaped in such a way that the inserted circuit boards are surrounded by the mounting elements in a U-shaped manner at two side regions of the circuit board running in the direction of the longitudinal axis of the circuit board, such that the side regions are guided in a type of groove within the mounting elements. Such fixing of the circuit boards to the receiving element is extremely unstable, such that the circuit boards can easily slip in an undesired manner within the receiving element, or even fall out.

Therefore, the invention is based on the object of providing a device for securing at least one circuit board to a receiving element which is distinguished by improved fixing of at least one circuit board to a receiving element.

The object is achieved according to the invention by means of the features of claim 1. Advantageous configurations of the invention are specified in the dependent claims.

The device according to the invention for securing at least one circuit board to a receiving element for receiving the at least one circuit board has a securing element. According to the invention, the securing element is led at least partly through a through-opening provided in the at least one circuit board, wherein the securing element has a first holding element, which can be secured on a surface of the at least one circuit board by a rotational movement of the securing element.

The securing element preferably has an elongate shaft which is led through the through-opening in the secured state of the securing element and extends from the circuit board to be secured as far as the receiving element. The through-opening can be embodied, for example, in round or angular fashion in the form of a circle, a square or alternatively in the form of an oblong hole. A first holding element is provided on the shaft of the securing element, by means of which the securing element can be secured, preferably clamped, on a surface of the at least one circuit board by a rotational movement of the securing element. In this case, the first holding element can be secured on that surface of the circuit board which faces away from the receiving element, such that the circuit board can be held preferably in a clamped manner between the receiving element and the holding element, whereby making it possible to prevent the circuit board from slipping from its desired position. The clamping of the holding element results in fixing of the circuit board in the desired position on the receiving element. In this case, the securing element can serve as additional securing alongside the securing of the circuit board in the groove-shaped cutouts of the mounting elements of the receiving element. If the receiving element is fashioned in such a way that it has a section on the mounting element into which the circuit board is only placed and is not guided in a groove, then the circuit board is substantially fixed to the receiving element by such a securing element. The securing element can be rotated into an open and into a closed position, wherein, in the open position, the securing element can be led at least partly through the through-opening provided in the circuit board and the circuit board is in an unsecured state. In this position, the first holding element is not secured on the surface of the circuit board. In the closed position, the first holding element is preferably rotated by an angle of 90° with respect to the open position, such that the holding element bears on the surface of the circuit board. In this position, the securing element is situated in the secured state and the circuit board is fixed in the desired position. Consequently, particularly secure and rapid fixing of at least one circuit board to a receiving element is then possible by means of the securing device according to the invention, wherein the securing element is embodied, in particular, as antitorsion/antitwist protection in the form of antivibration protection.

According to one advantageous configuration of the invention, the first holding element has a peripheral surface that is greater than the peripheral surface of the through-opening. Accordingly, in this case the first holding element is embodied with a size such that it cannot be led through the through-opening, rather only the shaft of the securing element and possible elements otherwise provided on the securing element can be led through the through-opening. If the securing element in the secured state is led through more than one circuit board, the first holding element, in the secured state of the securing element, accordingly preferably comes to bear on the surface of the topmost circuit board and fixes the latter.

It is preferably provided that the securing element has a second holding element, which can be secured on a surface of a second circuit board by a rotational movement of the securing element. The provision of a second holding element in addition to the first holding element makes it possible to fix two circuit boards simultaneously using one securing element. The first holding element is preferably arranged at a free end of the shaft of the securing element, wherein the second holding element is preferably provided below the first holding element on the shaft, such that, by means of the second holding element, a second circuit board provided below the first circuit board in the receiving element can be fixed with the second holding element. In this case, the securing element is embodied in such a way that, by means of a rotational movement of the securing element, it is possible both for the first holding element to be secured, preferably clamped, on the surface of the first circuit board and for the second holding element to be secured, preferably clamped, on the surface of the second circuit board.

In this case, the second holding element preferably has a peripheral surface that is less than the circumferential area of the through-opening. As a result, it is possible when securing the securing element, wherein the securing element is secured from above on the circuit boards, i.e. on that side of the circuit board which faces away from the receiving element, to lead the second holding element through the through-opening of the first circuit board, such that the second holding element can be secured, preferably clamped, on the surface of the second circuit board which is arranged below the first circuit board.

It is preferably provided that the first holding element is provided on the securing element in a manner offset with respect to the second holding element at an angle of substantially 90°. When the securing element is introduced through the through-openings of the circuit boards, in this case the securing element is rotated in such a way that the second holding element can be led through the through-opening of the first circuit board. In this case, the first holding element is preferably rotated in such a way that its longitudinal axis is oriented transversally with respect to the longitudinal axis of the through-openings, which are preferably embodied as an oblong hole. If the securing element has reached the desired end position for securing the circuit boards, then the securing element can be rotated by an angle of substantially 90°, such that the longitudinal axis of the second holding element is now formed transversally with respect to the longitudinal axis of the through-openings embodied as an oblong hole, for example, and, as a result, can now no longer slip out of the securing via the through-openings. By virtue of the fact that the peripheral surface of the first holding element is preferably made greater than the peripheral surface of the through-opening, the first holding element bears on the through-opening in the secured state of the securing element in such a way that the longitudinal axis of the first holding element is arranged parallel to the longitudinal axis of the through-opening, without the possibility that the first holding element might slip through the through-opening.

In accordance with a further preferred configuration of the invention, the securing element has more than one second holding element, wherein the plurality of second holding elements are oriented parallel to one another on the securing element. The plurality of second holding element preferably serve for fixing a plurality of circuit boards provided below the first circuit board by means of one securing element. For this purpose, the circuit boards respectively have through-openings arranged in alignment with one another on the respective circuit boards. By virtue of the fact that the second holding elements are arranged parallel to one another on the securing element, the second holding elements arranged on a shaft of the securing element can simultaneously have an open position, in which the second holding elements can be led through the through-openings in the circuit boards, and a closed position, in which the second holding elements bear on the surfaces of the respective circuit boards and fixedly clamp the latter. The rotational movement of the second holding elements provided on the securing element takes place simultaneously as a result. It is thus possible for a plurality of circuit boards provided in the receiving element, which are provided below the first circuit board, to be simultaneously fixed securely and rapidly in their desired position on the receiving element.

Furthermore, it is preferably provided that the securing element has a latching element, by means of which the securing element can be secured to the receiving element. The latching element is preferably arranged at an end of the shaft of the securing element which lies opposite the end of the shaft at which the first holding element is arranged. The latching element is preferably embodied as a latching hook by means of which the securing element can be secured on the receiving element by hooking, preferably by hooking into an undercut provided on the receiving element. In the region of the latching element, the shaft of the securing element is preferably embodied as a quadrilateral. The antitorsion protection of the securing element is preferably achieved by virtue of the fact that the diagonal dimension of the quadrilateral at the shaft of the securing element is greater than the width dimension of the receiving element in the region of the securing of the latching element. Upon rotation of the securing element, therefore, the receiving element deforms elastically in the region of the oversize and thus brings about the antitorsion protection, which is possible by virtue of the fact that the receiving element is preferably produced from an elastic plastics material. This principle of antitorsion protection can preferably also be applied in the case of the holding elements provided on the shaft of the securing element.

According to one preferred configuration of the invention, the latching element is provided on the securing element in a manner offset with respect to the first holding element at an angle of substantially 90°, such that the latching means, during the securing of the securing element, can be led through the through-openings in the circuit boards and is subsequently rotated during the rotational movement of the securing element in such a way that it can engage into the undercut on the receiving element and in this position can no longer be led through the through-openings.

In order to allow simple handling of the securing element for a user, the securing element preferably has an actuating area. The actuating area can be actuated by a user for example manually or by means of a tool, wherein the securing element can be positioned via the actuating area, in particular the rotational movement of the securing element can be exercised. The actuating area is in this case preferably formed on the first holding element, wherein the actuating area can be embodied in the form of a slot, into which a screwdriver can engage, for example, on the first holding element.

Furthermore, the invention relates to a receiving element for receiving at least one circuit board and a device embodied and developed as above for securing the at least one circuit board to the receiving element.

The invention is explained in greater detail below on the basis of preferred embodiments with reference to the accompanying drawings.

In the figures:

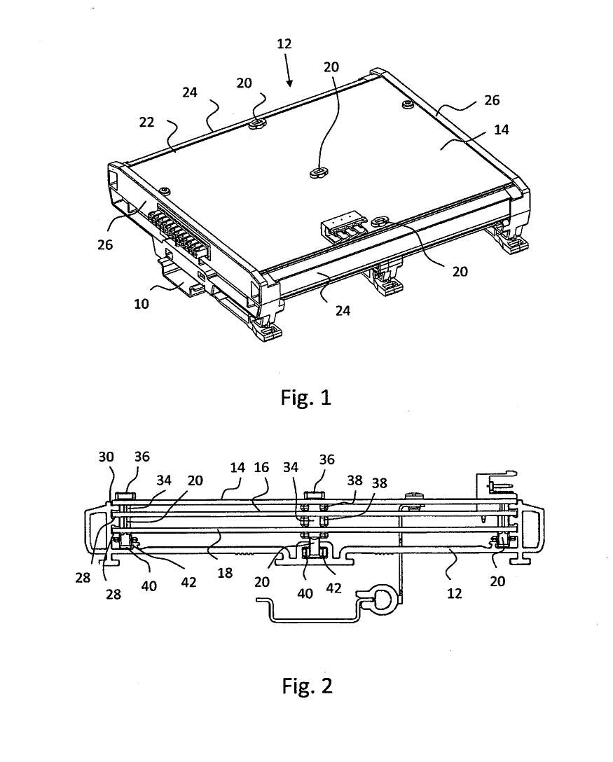

FIG. 1 shows a schematic illustration of a module unit according to the invention secured on a carrying rail;

FIG. 2 shows a schematic illustration of a plurality of securing devices according to the invention for securing a plurality of circuit boards to a receiving element of a module unit;

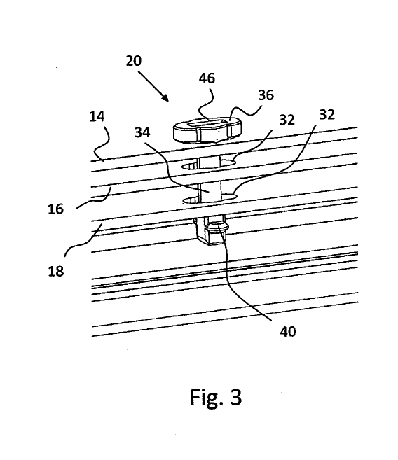

FIG. 3 shows a further schematic illustration of the securing device according to the invention provided on the circuit boards.

FIG. 1 shows a module unit according to the invention secured to a carrying rail 10. However, it is also possible to secure the module unit to a securing flange, not shown here. The module unit has a trough-shaped receiving element 12, as discernible in FIG. 2, for receiving at least one circuit board 14, 16, 18 wherein the receiving element 12 is shaped from an extrusion profile. The receiving element 12 is bounded or closed at its two longitudinal sides by a respective mounting element 24 having a plurality of insert regions or sections into which the circuit boards 14, 16, 18 can be inserted for securing to the receiving element 12.

The module unit shown in FIG. 1 has three circuit boards 14, 16, 18, which, as can be discerned in FIG. 2, are inserted into the receiving element 12 one above another. In FIG. 1, only the second circuit board 14 can be seen, which constitutes the topmost circuit board, and thus terminates the receiving element 12 or the module unit toward the top. Said second circuit board 14 bears on the mounting elements 24 and is secured to the receiving element 12 by means of three securing elements 20. In the example shown here, securing elements 20 are provided on the side regions 22 of the circuit boards 14, 16, 18 and in the middle of the circuit boards 14, 16, 18.

In order to prevent the circuit boards 14, 16, 18 from slipping out of the receiving element 12, a respective side element 26 is provided at the two transverse sides of the receiving element 12. The side elements 26 can be pushed onto the receiving element 12 and be secured there in a latching manner on the receiving element 12. The side elements 26 are embodied in such a way that they partly reach over the second circuit board 14 and can thereby protect the circuit board 14 from falling out of the receiving element 12 in an undesired manner.

FIG. 2 shows the receiving element 12 with the circuit boards 14, 16, 18 arranged therein, which are held in the receiving element 12 by means of sections 28, 30 provided on the mounting elements 24, wherein the sections 28 are preferably embodied in U-shaped fashion and the section 30 in L-shaped fashion. In addition thereto, the circuit boards 14, 16, 18 are fixed to the receiving element 12 by means of securing elements 20. For mounting the securing elements 20, the circuit boards 14, 16, 18 have through-openings 32, which, as discernible in FIG. 4, are embodied as an oblong hole.

The securing element 20 has an elongate shaft 34, on which a first holding element 36 is arranged and one or a plurality of second holding elements 38 can additionally be arranged. The first holding element 36 has a peripheral surface that is greater than the peripheral surface of the through-opening 32, such that the first holding element 36 is embodied with a size such that it cannot be led through the through-openings 32, rather only the shaft 34 of the securing element 20 and possible elements otherwise provided on the securing element 20 can be led through the through-openings 32, as can be discerned in the case of the securing element 20 provided at the side region 22. If the securing element 20 is led through more than one circuit board 14, 16, 18, the first supporting element 36, in the secured state of the securing element 20, as can be discerned in FIG. 2, accordingly preferably bears on the surface of the circuit board 14 which is provided as the topmost circuit board 14 in the receiving element 12.

The first holding element 36 is arranged at a free end of the shaft 34 of the securing element 20, wherein the second holding element 38 is provided below the first holding element 36 on the shaft 34, such that, by means of the second holding element 38, a second circuit board 16 provided below the first circuit board 14 in the receiving element 12 can be fixed with the second holding element 38, as can be discerned in the case of the securing element 20 arranged in the middle. In this case, the securing element 20 is embodied in such a way that, by means of a rotational movement of the securing element 20, it is possible both for the first holding element 36 to be clamped on the surface of the first circuit board 14 and for the second holding element 38 to be clamped on the surface of the second circuit board 16.

In this case, the second holding element 38 has a peripheral surface that is less than the peripheral surface of the through-opening 32. As a result, it is possible, when securing the securing element 20, wherein the securing element 20 is secured from above on the circuit boards 14, 16, 18, to lead the second holding element 38 through the through-opening 32 of the first circuit board 14, such that the second holding element 38 to clamp on the surface of the second circuit board 16 which is arranged below the first circuit board 14.

In this case, the first holding element 38 is provided on the securing element 20 in a manner offset with respect to the second holding element 38 at an angle of substantially 90°. When the securing element 20 is introduced into the circuit boards 14, 16, 18, in this case the securing element 20 is rotated in such a way that the second holding element 38 can be led through the through-opening 32 of the first circuit board 14. In this case, the first holding element 38 is preferably rotated in such a way that its longitudinal axis is oriented transversally with respect to the longitudinal axis of the through-opening 32, which is preferably embodied as an oblong hole. If the securing element 20 has reached the desired end position for securing the circuit boards 14, 16, 18, then the securing element 20 can be rotated by an angle of substantially 90°, such that the longitudinal axis of the second holding element 38 is now formed transversally with respect to the longitudinal axis of the through-opening 32 embodied as an oblong hole and, as a result, can now no longer slip out out of the securing via the through-opening 32. By virtue of the fact that the peripheral surface of the first holding element 36 is made greater than the peripheral surface of the through-opening 32, the first holding element 36 bears on the through-opening 32 in this state of the securing element 20 in such a way that the longitudinal axis of the first holding element 36 is arranged parallel to the longitudinal axis of the through-opening 32, without the possibility that the first holding element 36 might slip through the through-opening 32.

If a plurality of circuit boards 14, 16, 18, as is shown here, are arranged in the receiving element 12, then the circuit boards 14, 16, 18 respectively have, per securing element 20, a through-opening 32, which are arranged in alignment with one another, one above another, as shown in FIG. 4, such that the securing element 20 can be led by its shaft 34 through the through-holes 32 arranged one above another. Per circuit board 14, 16, 18, the securing element 20 can in this case respectively have a first holding element 36 and a second holding element 38, as is the case here for the securing element 20 arranged in the middle. In this case, the individual holding elements 36, 38, are preferably arranged at a specific distance from one another on the shaft 32, wherein the distance preferably corresponds to the distance between the circuit boards 14, 16, 18 to be secured.

In the region of the securing of the securing element 20 to the receiving element 12, the securing element 20 has a latching element 40, which can hook in the region of the receiving element 12, for example into an undercut 42 on a base plate 44 of the receiving element 12. The latching element 40 is arranged on the securing element 20 in a manner offset with respect to the first holding element 36 at an angle of substantially 90°, as can be discerned in FIG. 4, such that the latching element 40, during the securing of the securing element 20, can be led through the through-opening 32 in the circuit boards 14, 16, 18 and is subsequently rotated during the rotational movement of the securing element 20 in such a way that it can engage into the undercut 42 on the receiving element 12 and, as a result, can no longer be led through the through-openings 32.

In the exemplary embodiment shown in FIG. 2, a respective securing element 20 is provided at the side regions 22 of the circuit boards 14, 16, 18 wherein these securing elements 20 only fixedly clamp the first circuit board 14 by means of a first holding element 36, since the second circuit board 16 and the third circuit board 18 are held in their position in the receiving element 12 by the U-shaped sections 28 of the mounting elements 24 and the first circuit board 14 only bears on an L-shaped section 30, which does not reach over the first circuit board 14 toward the top. By contrast, the securing element 20 provided in the middle of the circuit boards 14, 16, 18 has a first holding element 36 for the first circuit board 14 and a respective second holding element 38 for the second circuit board 16 and the third circuit board 18, such that all three circuit boards 14, 16, 18 can be fixed by means of the holding elements 36, 38 centrally on the receiving element 12, as a result of which rattling noises caused by the circuit boards can be prevented.

FIG. 3 shows a detail illustration of a securing element 20 provided at the side regions 22 of the circuit boards 14, 16, 18, wherein this securing element 20 only has a first holding element 36, which bears on the first circuit board 14 in the secured state shown. The latching element 40, which can engage in an undercut 42 of the receiving element 12, is arranged on the shaft 34 in a manner offset with respect to the first holding element 36 by an angle of 90°.

In particular in order to be able to realize the rotational movement of the securing element 20, the securing element 20 has an actuating area 46, which is illustrated here in the form of a slot. The actuating area 46 is in this case formed on the top side of the first holding element 36, such that a user, for example by means of a screwdriver, can engage into the slotted actuating area 46 in order to be able to rotate the actuating element 20.

### LIST OF REFERENCE SIGNS

Carrying rail 10
Receiving element 12
First circuit board 14
Second circuit board 16
Third circuit board 18
Securing element 20
Side region 22
Mounting element 24
Side element 26
Section 28
Section 30
Through-opening 32
Shaft 34
First holding element 36
Second holding element 38
Latching element 40
Undercut 42
Base plate 44
Actuating area 46

1. A device for securing at least one circuit board to a receiving element for receiving the at least one circuit board, comprising a securing element, wherein the securing element is led at least partly through a through-opening provided in the at least one circuit board, wherein the securing element has a first holding element, which can be secured on a surface of the at least one circuit board by a rotational movement of the securing element.

2. The device as claimed in claim 1, wherein the first holding element has a peripheral surface that is greater than the peripheral surface of the through-opening.

3. The device as claimed in claim 1, wherein the securing element has a second holding element, which can be secured on a surface of a second circuit board by a rotational movement of the securing element.

4. The device as claimed in claim 3, wherein the second holding element has a peripheral surface that is less than the peripheral surface of the through-opening.

5. The device as claimed in claim 3, wherein the first holding element is provided on the securing element in a manner offset with respect to the second holding element at an angle of substantially 90°.

6. The device as claimed in claim 1, wherein the securing element has more than one second holding element, wherein the plurality of second holding elements are oriented parallel to one another on the securing element.

7. The device as claimed in claim 1, wherein the securing element has a latching element, by means of which the securing element can be secured to the receiving element.

8. The device as claimed in claim 7, wherein the latching element is provided on the securing element in a manner offset with respect to the first holding element at an angle of substantially 90°.

9. The device as claimed in claim 1, wherein the securing element has an actuating area.

10. A module unit, comprising a receiving element for receiving at least one circuit board and a device as claimed in claim 1 for securing the at least one circuit board to the receiving element.
